(19) United States
(12) Patent Application Publication
(10) Pub. No.: US 2023/0047001 A1
(43) Pub. Date: Feb. 16, 2023

(54) LIGHT-EMITTING DIODE AND LIGHT-EMITTING DEVICE INCLUDING THE SAME

(71) Applicant: Quanzhou Sanan Semiconductor Technology Co., Ltd., Nanan City (CN)

(72) Inventors: Kunta HSIEH, Nanan City (CN); Chunxiang WU, Nanan City (CN)

(21) Appl. No.: 17/818,381

(22) Filed: Aug. 9, 2022

(30) Foreign Application Priority Data
Aug. 16, 2021 (CN) 202110936747.8

(51) Int. Cl. H01L 33/38; H01L 33/62

(52) U.S. Cl. CPC H01L 33/382; H01L 33/62

(57) ABSTRACT

A light-emitting diode (LED) includes a substrate, an epitaxial structure, and first and second electrodes. The substrate has a surface with upper and lower edges, and two opposing side edges. The epitaxial structure is disposed on the surface. The first and second electrodes are disposed on the epitaxial structure. The second electrode includes a main portion and two extension portions. A projection of each of the extension portions on the surface extends in an extension direction away from the lower edge toward a corresponding one of the side edges in such a manner that an included angle between an central axis perpendicular to the bottom edge and a tangent line of any point on the projection of the extension portions on the surface is not greater than 90° and increases along the extension direction.

### CROSS-REFERENCE TO RELATED APPLICATION

This application claims priority of Chinese Invention Patent Application No. 202110936747.8, filed on Aug. 16, 2021.

### FIELD

The disclosure relates to a light-emitting diode and a light-emitting device including the same.

### BACKGROUND

Light-emitting diode (LED) is a solid-state semiconductor device that converts electrical energy into light energy. When an electrical current is applied to an LED, recombination of electrons and holes generated from predetermined p-type and n-type semiconductor layers occur so as to emit light with a desired wavelength. In comparison with other conventional lighting devices, LED has many advantageous properties such as a long service life, a high light efficiency, a low power consumption, and being relatively environmentally friendly. Currently, LED is mainly used in display monitor, indicator light and backlight.

Advancement in development of LED is highly urged so as to prolong the service life and to improve the reliability and light-emitting efficiency of LED. For example, US Patent Application Publication No. US 2014/0217510 A1 discloses a semiconductor device that includes a comb-like n-type metal-oxide-silicon (MOS) transistor which is used as an electrostatic discharge protection element, and which is capable of being operated uniformly. By adjusting a length of a gate electrode of the n-type MOS transistor according to a distance between the n-type MOS transistor and a substrate contact whose potential is fixed at the ground potential, a respective one of the teeth of the gate electrode can uniformly enter snap-back operation, so as to avoid local concentration of current, and to obtain a desired electrostatic discharge (ESD) tolerance.

Referring to FIG. 1, a conventional LED includes a substrate 91, an epitaxial structure 92 disposed on the substrate 91, and first and second electrodes 93, 94 that are disposed on the epitaxial structure 92 opposite to the substrate 91. The second electrode 94 includes a main portion 942 that is located around a corner of an upper surface of the epitaxial structure 92, and two extension portions 941 that extend linearly away from the main portion 942. With such configuration, a current tends to concentrate around the extension portions 941, which might cause poor current spreading and overloading of the extension portions 41, resulting in reduced brightness and non-uniform brightness of the conventional LED.

### SUMMARY

Therefore, an object of the disclosure is to provide a light-emitting diode (LED) and a light-emitting device that can alleviate at least one of the drawbacks of the prior art.

According to the disclosure, the LED includes a substrate, an epitaxial structure, a first electrode and a second electrode. The substrate has a surface with an upper edge, a lower edge, and two opposing side edges that extend between the upper and lower edges. The epitaxial structure is disposed on the surface of the substrate, and includes a first semiconductor layer, a second semiconductor layer and an active layer interposed between the first and second semiconductor layers. The first electrode is disposed on the first semiconductor layer. The second electrode is disposed on the second semiconductor layer, and includes a main portion and two extension portions that extend away from the main portion. A projection of each of the extension portions on the surface extends in an extension direction away from the lower edge toward a corresponding one of the side edges in such a manner that an included angle between a central axis perpendicular to the bottom edge and a tangent line of any point on the projection of each of the extension portions on the surface is not greater than 90°, and increases along the extension direction.

According to the disclosure, the light-emitting device includes at least one the abovementioned LED.

### BRIEF DESCRIPTION OF THE DRAWINGS

Other features and advantages of the disclosure will become apparent in the following detailed description of the embodiments with reference to the accompanying drawings, of which:

FIG. 1 is a schematic top view illustrating a conventional light-emitting diode (LED);

FIG. 2 is a schematic cross-sectional view illustrating a first embodiment of an LED according to the disclosure;

FIG. 3 is a schematic top view illustrating the first embodiment of the LED according to the disclosure;

FIG. 4 is a schematic top view of a variation of the first embodiment of the LED which illustrates a distance between a bottom edge of a substrate and a projection of two extension portions of a second electrode on the substrate;

FIG. 5 is a schematic top view of another variation of the first embodiment of the LED which illustrates a distance between side edges of the substrate and the projection of the extension portions of the second electrode on the substrate;

FIG. 6 is a schematic top view of the first embodiment which illustrates a distance between the two extension portions of the second electrode along an extension direction;

FIG. 7 is a schematic graph illustrating the projection of the extension portions of the first embodiment, in which an included angle is defined between a central axis and a tangent line of a given point on the projection of the extension portions along an extension direction;

FIG. 8 is a graph showing antistatic ability of the first embodiment of the LED and the conventional LED shown in FIG. 1 at different voltage levels;

FIG. 9 is a graph showing output power versus current of the first embodiment of the LED and the conventional LED;

FIG. 10 is a schematic top view illustrating a second embodiment of the LED according to the disclosure;

FIG. 11 is a schematic graph illustrating the projection of the extension portions of the second embodiment, in which an included angle is defined between a central axis and a tangent line of a given point on the projection of the extension portions along an extension direction;

FIG. 12 is a schematic top view illustrating a third embodiment of the LED according to the disclosure;

FIG. 13 is a schematic graph illustrating the projection of the extension portions of the third embodiment, in which an included angle is defined between a central axis and a tangent line of a given point on the projection of the extension portions along an extension direction;

FIG. 14 is a schematic top view illustrating a fourth embodiment of the LED according to the disclosure;

FIG. 15 is a schematic graph illustrating the projection of the extension portions of the fourth embodiment, in which an included angle is defined between a central axis and a tangent line of a given point on the projection of the extension portions along an extension direction;

FIG. 16 is a schematic top view illustrating a fifth embodiment of the LED according to the disclosure;

FIG. 17 is a schematic graph illustrating the projection of the extension portions of the fifth embodiment, in which an included angle is defined between a central axis and a tangent line of a given point on the projection of the extension portions along an extension direction; and

FIG. 18 is a schematic view illustrating a light-emitting device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

For purposes of description herein, the terms “upper”, “lower”, “side”, “top”, “bottom”, and derivatives thereof relate to the disclosure as oriented in the figures and is not to be construed as limiting any feature to be a particular orientation, as said orientation may be changed based on the user's perspective of the device.

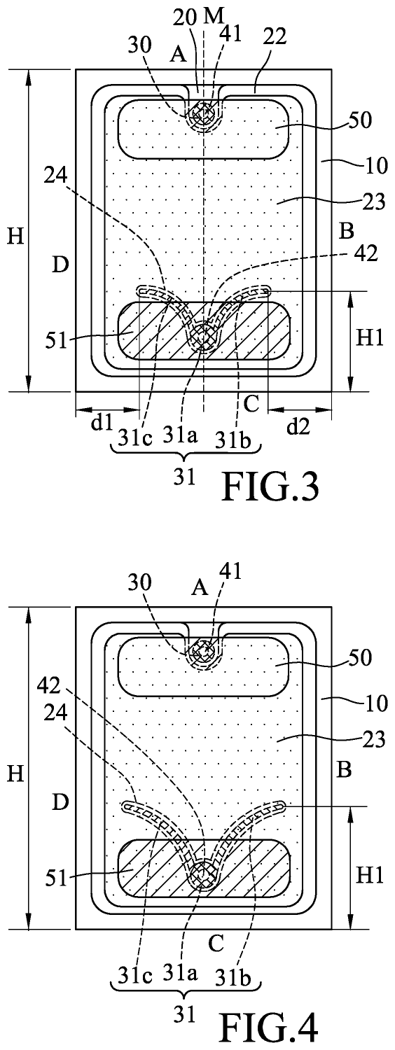

Referring to FIGS. 2 and 3, a first embodiment of a light-emitting diode (LED) according to the disclosure includes a substrate 10, an epitaxial structure, a first electrode 30 and a second electrode 31.

The substrate 10 has a top surface on which the epitaxial structure is disposed, and a bottom surface that serves as a light-emitting surface of the LED. The top surface has an upper edge A, a lower edge C, and two opposing side edges B, D that extend between the upper and lower edges A, C. In this embodiment, the LED is a rectangular LED, and the substrate 10 is substantially rectangular. A length of each of the side edges B, D may be not greater than twice of a length of each of the upper and lower edges A, C. The length of each of the side edges B, D may be not shorter than the length of each of the upper and lower edges A, C.

The substrate 10 may be an insulating substrate or a conductive substrate. The substrate 10 may serve as a growth substrate for growth of the epitaxial structure. In certain embodiments, the substrate 10 is a sapphire substrate.

The substrate 10 may be a regular or irregular patterned substrate which is formed with a plurality of protrusions (not shown in figures) on the top surface thereof. The protrusions may be formed by nano imprint lithography, dry etching or wet etching. The protrusions may be made of a material identical to that of the substrate 10, such as a sapphire material. Alternatively, the protrusions may be made of a material different from that of the substrate 10, such as a low-refractive-index material that may reflect light emitted from the epitaxial structure, e.g., Al₂O₃, SiO, SiO2, Si₃N₄, ZnO₂ or combinations thereof. The protrusions may be composed of alternately stacked layers. The protrusions may also be configured to diffract the light, so as to improve light-emitting efficiency of the LED. It is noted that the shape and size of the protrusions may be adjusted according to practical need so as to further improve light-emitting efficiency of the LED. For example, each of the protrusions may be formed in a shape of a platform, a cone, a pyramid, a cone-like structure or a pyramid-like structure, but are not limited thereto. Each of the protrusions may have a height ranging from 1 μm to 3 μm, such as not less than 1.5 μm, e.g., ranging from 1.8 μm to 2.2 μm.

The epitaxial structure is disposed on a portion of the top surface, such that a portion of the protrusions located around the periphery of epitaxial structure are exposed from the epitaxial structure. Such configuration may avoid bowing and damage of the epitaxial structure during a manufacture process of the LED, so as to improve production yield of the LED. In addition, stress of the epitaxial structure may be reduced, and thus the substrate 10 may be further thinned to reduce thickness thereof.

The epitaxial structure may be grown on the substrate 10 by an appropriate epitaxial process, for instance, metal organic chemical vapor deposition (MOCVD), hydride vapor phase epitaxy (HVPE), or molecular beam epitaxy (MBE), but is not limited thereto. The epitaxial structure may have a thickness ranging from 2 μm to 6 μm.

The optical properties (such as light-emitting angle and wavelength distribution) and electrical properties (such as forward voltage or current flow) of the LED may depend on the structure and composition of the epitaxial structure. In this embodiment, the epitaxial structure includes a first semiconductor layer 20, an active layer 21 and a second semiconductor layer 22 that are sequentially disposed on the top surface of the substrate 10 in such order.

The first and second semiconductor layers 20, 22 have opposite electrical conductivities. Each of the first and second semiconductor layers 20, 22 may be made of a group II-VI material, such as zinc selenide (ZnSe), or a group III-V nitride-based material, such as gallium nitride (GaN), aluminum nitride (AlN), indium nitride (InN), indium gallium nitride (InGaN), aluminum gallium nitride (AlGaN) or aluminum indium gallium nitride (AlInGaN). The first semiconductor layer 20 may be an n-type semiconductor layer for providing electrons, and may be doped with an n-dopant such as silicon (Si) or germanium (Ge). The second semiconductor layer 22 may be a p-type semiconductor layer for providing holes, and may be doped with a p-dopant such as magnesium (Mg) or carbon (C). Each of the first and second semiconductor layers 20, 22 may have a single-layer structure or a multi-layered structure.

When a current is applied to the LED, the electrons and holes from the first and second semiconductor layers 20, 22 will recombine at the active layer 21 to generate light. According to the material of the epitaxial structure, the LED may emit light with a desired wavelength, such as ranging from 380 nm to 700 nm. For example, when the epitaxial structure includes an AlInGaP-based material, the LED may emit a red light with a wavelength ranging from 610 nm to 650 nm, or a yellow light with a wavelength ranging from 530 nm to 570 nm. When the epitaxial structure includes an InGaN-based material, the LED may emit a blue light with a wavelength ranging from 400 nm to 490 nm, or a green light with a wavelength ranging from 490 nm to 550 nm. When the epitaxial structure includes an AlGaN-based material, the LED may emit an ultraviolet light with a wavelength ranging from 250 nm to 400 nm.

In certain embodiments, the active layer 21 includes at least one intrinsic (undoped) semiconductor sublayer or a lightly-doped semiconductor sublayer. The active layer 21 may be a quantum well layer, in which collision probability of the electrons and the holes is increased so as to improve recombination efficiency thereof, thereby improving light-emitting efficiency of the LED. The active layer 21 may be configured as a single heterostructure (SH), a double heterostructure (DH), a double-sided double heterostructure (DDH) or a multi-quantumwell (MQW) structure.

In certain embodiments, the LED may further include a buffer layer (not shown in figures) which is formed between the top surface of the substrate 10 and the epitaxial structure, so as to reduce lattice mismatch between the substrate 10 and the epitaxial structure. The buffer layer may be made of a GaN-based material such as AlGaN, or an AlN-based material. The buffer layer may have a single-layer structure or a multi-layered structure. Examples of a process for forming the buffer layer may include, but are not limited to, a MOCVD process, a MBE process and a physical vapor deposition (PVD) process such as sputtering, reactive sputtering and evaporation deposition (e.g., electron beam evaporation deposition or thermal evaporation deposition). In certain embodiments, sputtering is adopted to permit the buffer layer comprised of AlN to be conformally formed on the protrusions of the substrate 10 with high uniformity and compactness.

In this embodiment, the epitaxial structure is etched downwardly from the second semiconductor layer 22 in such manner that a portion of the first semiconductor layer 20 is exposed, and a mesa structure for disposal of the first and second electrodes 30, 31 is formed. An etched thickness may range from 1 μm to 2 μm.

The first and second electrodes 30, 31 are independently made of a metallic material. Examples of the metallic material may include, but are not limited to, nickel, gold, chromium, titanium, platinum, palladium, rhodium, iridium, aluminum, tin, indium, tantalum, copper, cobalt, iron, ruthenium, zirconium, tungsten, molybdenum, and combinations thereof. Each of the first and second electrodes 30, 31 may be formed as a multi-layered structure which may include a contact layer, a reflective layer, a blocking layer and an adhesive layer. In certain embodiments, the contact layer is made of chromium, the reflective layer is made of aluminum, the blocking layer is made of titanium, platinum, nickel or combinations thereof, and the adhesive layer is made of titanium. The adhesive layer may be attached onto an insulating layer 40 of the LED, which will be described hereinafter.

The first electrode 30 is formed on and in ohmic contact with the exposed portion of the first semiconductor layer 20. As shown in FIG. 3, a projection of the first electrode 30 on the top surface of the substrate 10 is located near the upper edge A, which is a shorter edge of the rectangular LED. The projection of the first electrode 30 may be formed in a shape of circle, oval, horseshoe, etc. In other embodiments, the first electrode 30 has a configuration different from that shown in FIG. 3. For example, the first electrode 30 may include a main portion and two extension portions that are located on two opposite sides of the main portion and that extend from the main portion, e.g., in a direction parallel to the upper edge A. To maximize a light-emitting area of the LED, such extension portions of the first electrode 30 may be omitted.

The second electrode 31 is disposed on and is in ohmic contact with the second semiconductor layer 22. To spread a current from the second electrode 31 more evenly into the second semiconductor layer 22, the first embodiment of the LED further includes a current spreading layer 23 formed on the second semiconductor layer 22 opposite to the active layer 21, and the second electrode 31 is immediately formed on the current spreading layer 23. The current spreading layer 23 may be made of a transparent conductive material such as a conductive oxide, so as to enhance reliability of the LED. Examples of the transparent conductive material may include, but are not limited to, indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO) and zinc oxide (ZnO). The current spreading layer 23 may be formed by a deposition process such as chemical vapor deposition (CVD), atomic layer deposition (ALD), or any other appropriate process. The current spreading layer 23 may have a single-layer structure or a multi-layered structure such as a distributed Bragg reflector (DBR) structure.

The LED further includes an insulating layer 40 that is disposed over the epitaxial structure, and the first electrode 30 and the second electrode 31 opposite to the substrate 10, i.e., disposed to cover an upper surface and a lateral surface of the epitaxial structure, the current spreading layer 23, the first electrode 30 and the second electrode 31 opposite to the substrate 10, as well as on the top surface of the substrate 10 that is not covered by the epitaxial structure. The insulating layer 40 covering the lateral surface of the epitaxial structure may prevent electrical leakage from occurring, so as to avoid short circuit of the LED.

The insulating layer 40 may be made of an electrically insulating material, such as an inorganic material or a dielectric material. The inorganic material may include silicone or glass. The dielectric material may include aluminum oxide (Al₂O₃), silicon nitride (SiNₓ), silicon oxide (SiOₓ), titanium oxide (TiOₓ) or magnesium fluoride (MgFₓ). In certain embodiments, the insulating layer 40 may be made of at least one of the following materials: silicon dioxide, silicon nitride, titanium oxide, tantalum oxide, niobium oxide, and barium titanate. The insulating layer 40 may be made by alternately stacking any two of such materials so as to form a DBR.

In this embodiment, the insulating layer 40 is formed with a first through hole 41 that partially exposes the first electrode 30, and a second through hole 42 that partially exposes the second electrode 31.

The LED may further include a first pad electrode 50 and a second pad electrode 51. The first pad electrode 50 is disposed on the insulating layer 40, and fills the first through hole 41 to be electrically connected to the first electrode 30. The second pad electrode 51 is disposed on the insulating layer 40, and fills the second through hole 42 to be electrically connected to the second electrode 31. The first and second pad electrodes 50, 51 may be N-type and P-type pad electrodes, respectively. The first and second pad electrodes 50, 51 may be formed as, but is not limited to, a square column. The first and second pad electrodes 50, 51 may be simultaneously formed using identical materials, and may have identical structures. For example, each of the first and second pad electrodes 50, 51 has a multi-layered structure which may sequentially include an adhesive layer, a reflective layer, a stress relieving layer, an eutectic layer and a top layer in a direction away from the epitaxial structure. The adhesive layer may be made of chromium or titanium, and is disposed to adhere to the insulating layer 40. The reflective layer may be made of aluminum. The stress relieving layer may be composed of an alternate stacking of a titanium layer and an aluminum layer. The eutectic layer may be a combination of a nickel layer and a platinum layer. In certain embodiments, the nickel layer is stacked on the platinum layer. In such case, the nickel layer may be more proximate to the insulating layer 40 than the platinum layer, or vice versa. Alternatively, the eutectic layer may be a nickel layer which is sufficient to form an excellent eutectic system, but may generate a relatively large stress, which, however, may be relieved by the stress relieving layer. A total thickness of the nickel layer may be controlled within a range of 550 nm to 750 nm so as to reduce generation of stress. The top layer may be made of tin, gold or a combination thereof. When a voltage is applied to the first and second pad electrodes 50, 51, the current flows from the second pad electrode 51 to the first pad electrode 50 and spreads throughout the epitaxial structure to allow the recombination of electrons and holes in the active layer 21, thus emitting light.

The LED may further include a current blocking layer 24 that is disposed between the second semiconductor layer 22 and the current spreading layer 23, and that is located at a position corresponding to a projection of the second electrode 31 on the second semiconductor layer 22. The current blocking layer 24 is configured to block transmission of the applied current directly and vertically from the second electrode 31 to the second semiconductor layer 22, which is conductive to laterally spreading the current in the current spreading layer 23. The current blocking layer 24 may be made of a material identical to that of the insulating layer 40. The current blocking layer 24 may be formed as a continuous structure, or a discrete structure. In certain embodiments, the current blocking layer 24 is formed in a shape identical to the second electrode 31. In addition, the current blocking layer 24 may have a width greater than that of the second electrode 31. That is, an area of a projection of the current blocking layer 24 on the top surface of the substrate 10 is greater than that of the projection of the second electrode 31. For example, a periphery of the projection of the current blocking layer 24 may extend a distance of at least 2 μm outwardly away from a periphery of the projection of the second electrode 31.

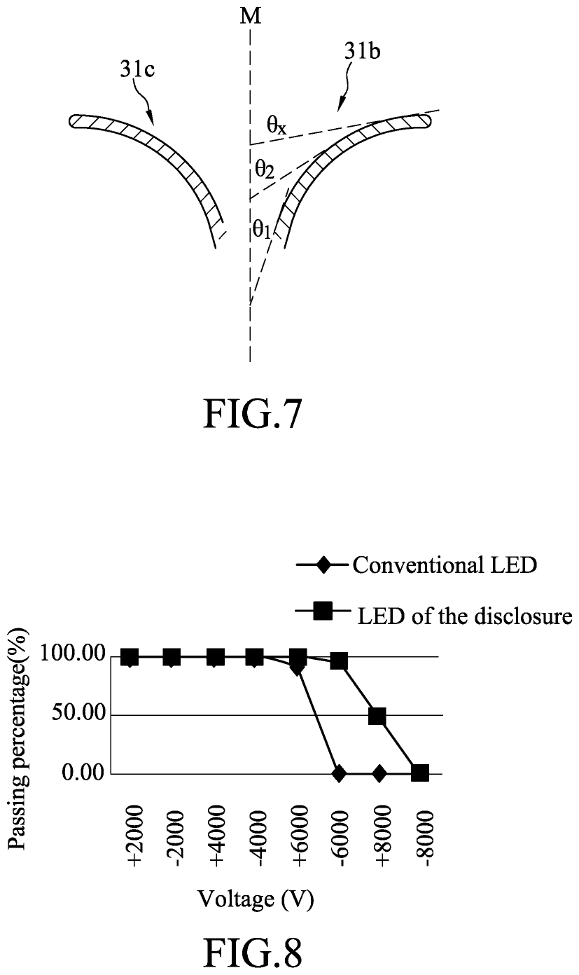

Referring to FIGS. 3, 6 and 7, the second electrode 31 includes a main portion 31a and two extension portions 31b, 31c that extend away from the main portion 31a. A projection of the main portion 31a on the top surface of the substrate 10 is more proximal to the lower edge C than to the upper edge A. The projection of the main portion 31a may lie on a central axis M that is perpendicular to the lower edge C (for the rectangular LED, the central axis M is also parallel to the side edges B, D) and that passes through a centroid of the top surface of the substrate 10. Each of the extension portions 31b, 31c may independently extend from the main portion 31a. A projection of each of the extension portions 31b, 31c on the surface extends in an extension direction away from the lower edge C toward a corresponding one of the side edges B, D in such a manner that an included angle (θ₁, θ₂, . . . θₓ) between the central axis M and a tangent line of any point on the projection of each of the extension portions 31b, 31c on the top surface is not greater than 90°. The included angle increases along the extension direction, i.e., θ₁<θ₂ . . . <θₓ. The projection of each of said extension portions 31b, 31c has two opposite sides, one of which concavely faces the lower edge C, and the other one of which convexly faces the upper edge A.

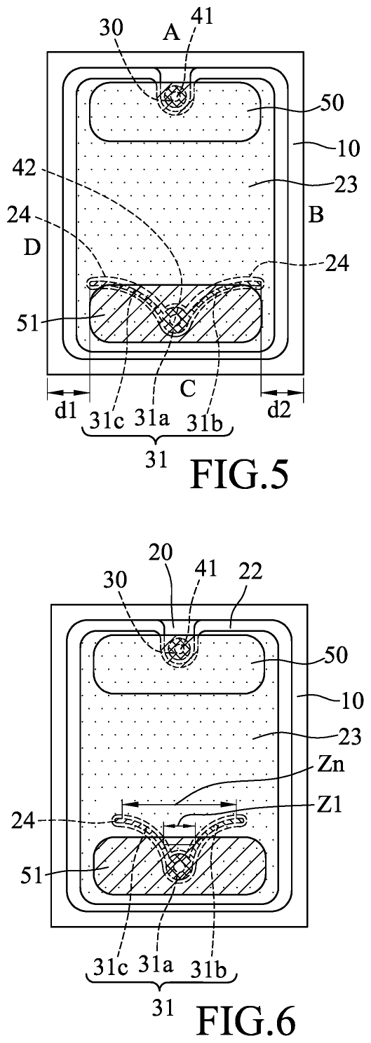

In this embodiment, each of the extension portions 31b, 31c is formed as an arc structure. In certain embodiments, respective points of the projections of the extension portions 31b, 31c at the same height level (i.e., with the same distance to the lower edge C) have a distance (Z1 . . . Zn) which is parallel to the lower edge C and which gradually increases along the extension direction (see FIG. 6).

A radius of curvature of each of the extension portions 31b, 31c may be adjusted according to a length of each of the extension portions 31b, 31c and/or a desired size of the LED. The radius of curvature may be not greater than 100 μm, e.g., 99.99 μm, 99.98 μm, 99.97 μm, etc. The radius of curvature of each of the extension portions 31b, 31c may also be changed based on the degree of uniformity of current spreading to be achieved. In certain embodiments, the radius of curvature is constant along the extension direction. In other embodiments, the radius of curvature gradually increases along the extension direction. In this embodiment, the radius of curvature of each of the extension portions 31b, 31c is 100 μm. In order to achieve an improved current spreading effect, the extension portions 31b, 31c may extend in a symmetrical manner.

A cross section of each of the extension portions 31b, 31c perpendicular to the extension direction has a bottom width which is proximal to the epitaxial structure, and which may range from 2 μm to 10 μm. The cross section of each of the extension portions 31b, 31c may have a trapezoid shape. The bottom width of each of the extension portions 31b, 31c may be constant along the extension direction. In certain embodiments, a terminal point of each of the extension portions 31b, 31c opposite to the main portion 31a may have an enlarged portion which has a bottom width greater than that of the remainder of the extension portions 31b, 31c, so as to avoid electrostatic breakdown due to weak antistatic ability.

When the upper edge A and the lower edge C of the top surface are spaced apart from each other by a distance H, a distance H1 between the lower edge C and a terminal point on the projection of each of the extension portions 31b, 31c which is farthest from the main portion 31a may range from 0.15 H to 0.6 H, such as 0.16 H, 0.17 H, 0.58 H, 0.59 H, etc. Referring to FIG. 4, in a variation of the first embodiment, the distance H1 is greater than that of the first embodiment. Such arrangement may be capable of further improving the degree of uniformity of current spreading, thereby increasing antistatic ability of the LED.

It is noted that as the length of each of the extension portions 31b, 31c increases, current spreading effect is typically improved, which in turn increases antistatic ability of the LED. Moreover, in order to avoid electrostatic breakdown due to weak antistatic ability as much as possible, the terminal point on the projection of each of the extension portions 31b, 31c should not be too close to the side edges B, D. For example, a minimal distance d1, d2 between the terminal point on the projection of each of the extension portions 31b, 31c and a respective one of the side edges B, D may range from 5 μm to 40 μm, such as 5.01 μm, 5.02 μm, 39.98 μm, 39.99 μm, etc. In this embodiment, both d1 and d2 are the same. Referring to FIG. 5, in another variation of the first embodiment, both d1 and d2 are shorter than those of the first embodiment, i.e., the terminal point on the projection of each of the extension portions 31b, 31c is more proximal to the respective one of the side edges B, D.

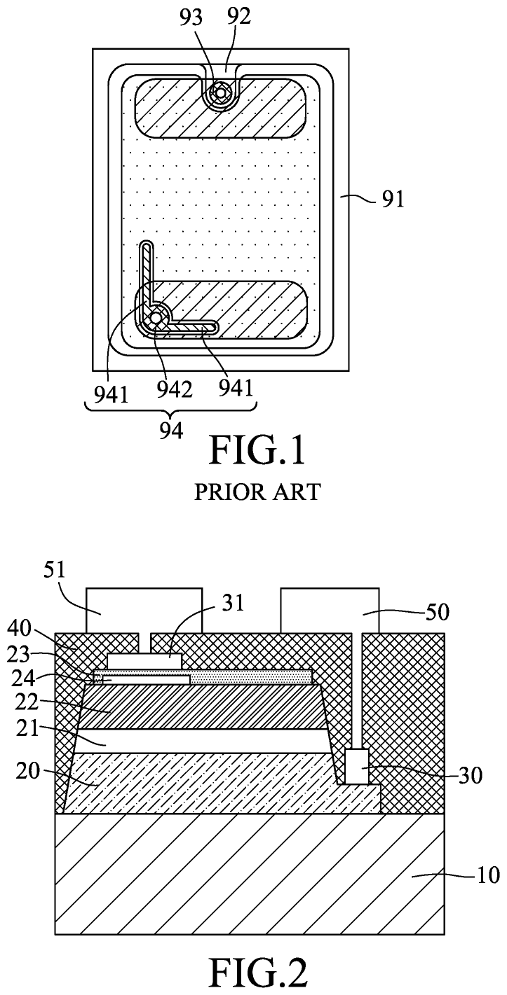

To evaluate the antistatic effect of the LED, 100 LEDs of the first embodiment serving as test samples are subjected to an electrostatic discharge (ESD) withstand test by applying different voltages thereto. The test samples without being damaged by the applied voltage are determined to pass the ESD with stand test, while the test samples that are damaged under the applied voltage are determined to fail the ESD withstand test. A passing percentage is calculated based on the formula: n/100×100%, in which n represents the number of the testing samples passing the ESD withstand test). The results of the ESD withstand test are shown in FIG. 8. In comparison, 100 conventional LEDs shown in FIG. 1 (each of which only differs from the first embodiment in terms of the configuration of the extension portions of the second electrode) are subjected to the same test. As shown in FIG. 8, the LED of the first embodiment has a higher passing percentage, and an enhanced ESD withstanding voltage as compared to the conventional LED, indicating that the LED of the first embodiment has an improved antistatic ability compared with the conventional LED, and thus can effectively avoid damage or electrostatic breakdown due to weak antistatic ability.

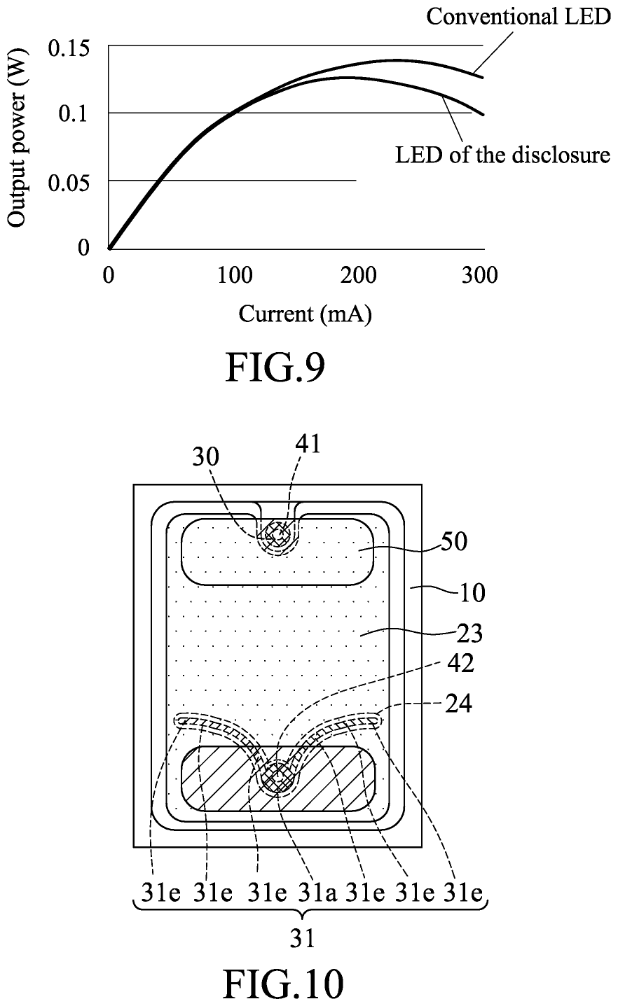

Furthermore, the LED of the first embodiment and the conventional LED are subjected to determination of light output power at different current levels. As shown in FIG. 9, as the current level gradually increases, the LED of the first embodiment shows a higher light output power than that of the conventional LED. These results indicate that, with the extended configuration of the extension portions 31b, 31c, the LED of this disclosure is conferred with an improved saturation current stability, resulting in improved reliability of the LED.

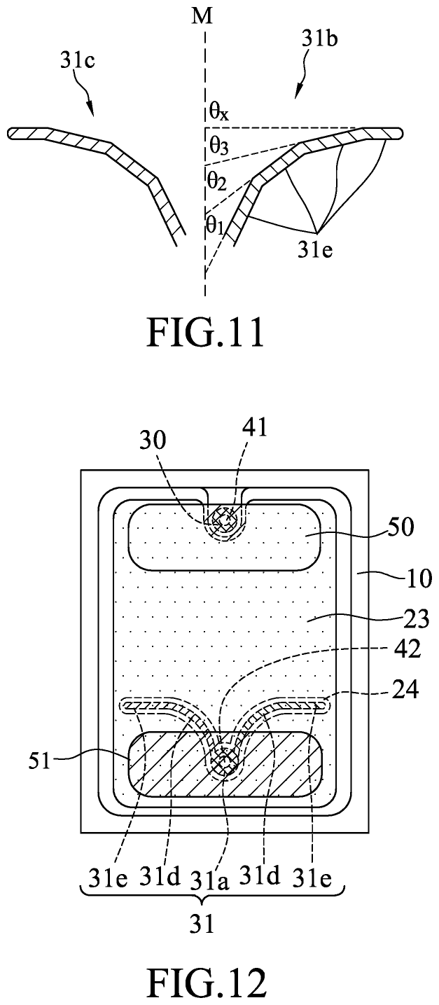

Referring to FIGS. 10 and 11, a second embodiment of the LED is generally similar to the first embodiment, except for the configuration of the extension portions 31b, 31c of the second electrode 31. Specifically, in the second embodiment, each of the extension portions 31b, 31c includes a plurality of straight segments 31e with different slopes that are consecutively connected to each other along the extension direction. The included angles θ1, θ2 . . . θx formed between the central axis M and a projection of each of the straight segments 31e on the top surface of the substrate 10 increase along the extension direction. That is, along the extension direction, the slopes of the consecutive straight segments 31e become closer to zero.

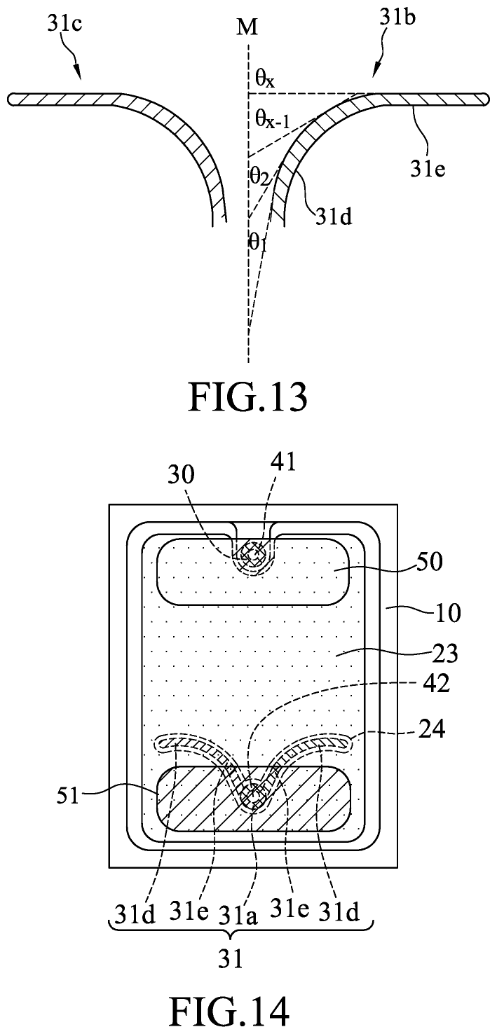

Referring to FIGS. 12 and 13, a third embodiment of the LED is generally similar to the first embodiment, except for the configuration of the extension portions 31b, 31c of the second electrode 31. Specifically, in the third embodiment, each of the extension portions 31b, 31c sequentially includes a curved segment 31d and a straight segment 31e along the extension direction. That is, the curved segment 31d extends from the main portion 31a of the second electrode 31, and the straight segment 31e is connected to and extends from the curved segment 31d opposite to the main portion 31a. Along the extension direction, tangent lines of points on a projection of the curved segment 31d on the top surface of the substrate 10 respectively form included angles θ1, θ2 . . . θx−1 with the central axis M which gradually increase, i.e., θ1<θ2< . . . θx−1. A projection of the straight segment 31e on the top surface forms an included angle θx with the central axis M, and θx>θx−1, and θx may be equal to or lower than 90°.

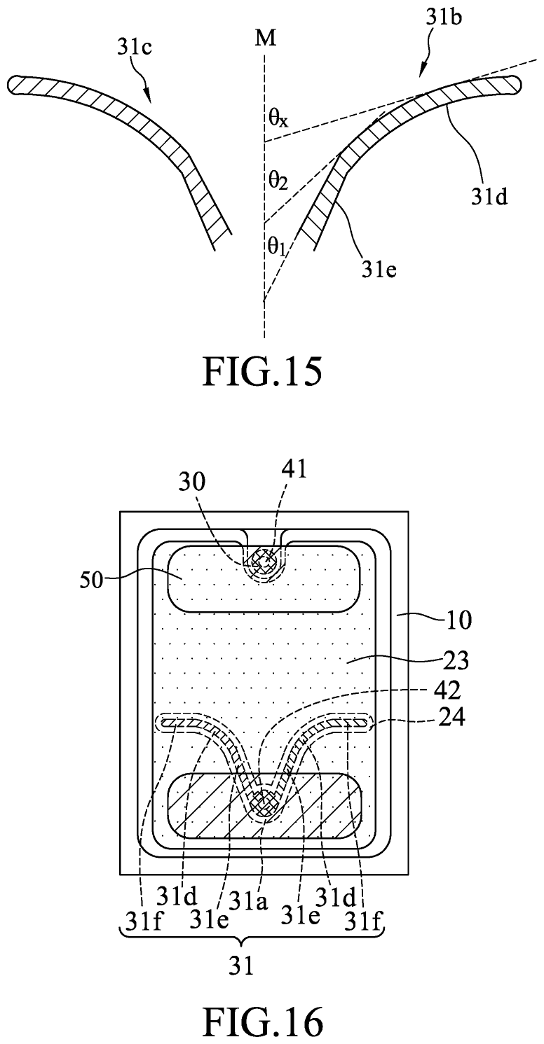

Referring to FIGS. 14 and 15, a fourth embodiment of the LED is generally similar to the first embodiment, except for the configuration of the extension portions 31b, 31c of the second electrode 31. Specifically, in the fourth embodiment, each of the extension portions 31b, 31c sequentially includes a first straight segment 31e and a curved segment 31d. That is, the first straight segment 31e extends from the main portion 31a, and the curved segment 31d is connected to and extends from the first segment 31e opposite to the main portion 31a. A projection of the first straight segment 31e on the top surface of the substrate 10 forms an included angle θ1 with the central axis M. Along the extension direction, tangent lines of points on a projection of the curved segment 31d on the top surface of the substrate 10 respectively form included angles θ2, θ3, . . . θx with the central axis M. θ2 is greater than θ1, and θ2, θ3, . . . and θx gradually increase along the extension direction.

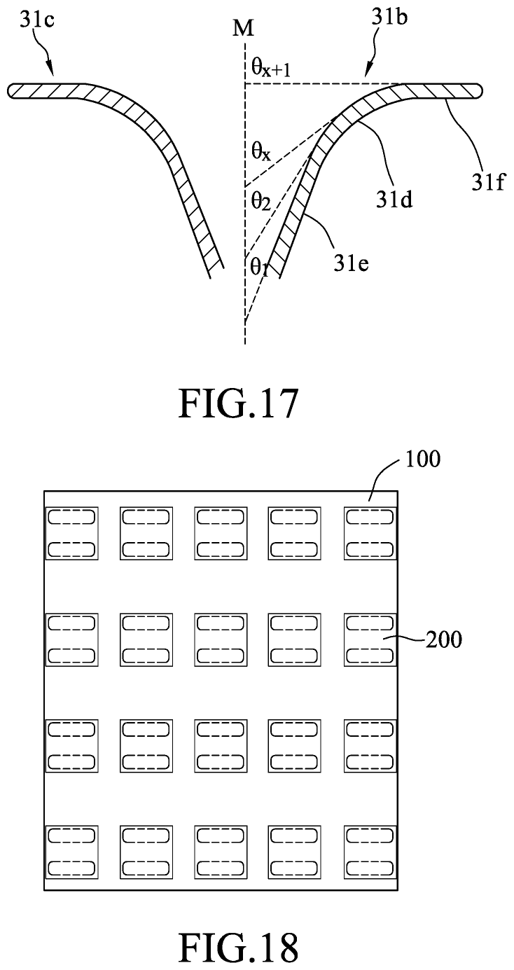

Referring to FIGS. 16 and 17, a fifth embodiment of the LED is generally similar to the fourth embodiment, except that in the fifth embodiment, each of the extension portions 31b, 31c further includes a second straight segment 31f that is connected to and extends from the curved segment 31d opposite to the first straight segment 31e. A projection of the second straight segment 31f on the top surface of the substrate 10 forms an included angle θx+1 with the central axis M, and θx+1>θx, and θx+1 is equal to or lower than 90°.

The LED of the disclosure may be applied in a light-emitting module. Specifically, the first and second pad electrodes 50, 51 of the LED are connected to a circuit board through a solder paste by reflow soldering at high temperature so as to form a light-emitting module.

The light-emitting module may be further used in different light-emitting device such as a display device, for instance, a backlight display and a RGB display, e.g., television, mobile phone, tablet, computer or outdoor display screen. Referring to FIG. 18, the light-emitting device according to the disclosure includes a frame 100, and at least one the abovementioned LED that adopts flip-chip packaging and that is denoted as flip-chip LED 200 in FIG. 18. The flip-chip LED 200 is mounted onto the frame 100.

Examples of the frame 100 may include, but are not limited to, a chip-on-board (COB) frame, a chip-on-glass (COG), or a surface-mount-device (SMD) frame. The frame 100 may be a flat frame, or may be formed with a reflecting cavity which is defined by a reflecting wall that surrounds the flip-chip LED 200. The flip-chip LED 200 is disposed within the reflecting cavity.

The frame 100 includes metal electrodes that have opposite polarities. The first and second pad electrodes 50, 51 are eutectically bonded to respective ones of the metal electrodes of the frame 100 through, e.g., a solder paste by a thermal reflow process. A plurality of the flip-chip LEDs 200 may be integrated onto an application substrate or a packaging substrate in the aforesaid manner to form a backlight device or a light source of a RGB display device.

In sum, the configuration of the extension portions 31b, 31c is advantageous in various aspects, for instance, in combination with the current spreading layer 23, current may be spread more uniformly, i.e., laterally throughout the second semiconductor layer 22 instead of concentrating around the second electrode 31, and thus uniformity and brightness of light emitted by the LED may be improved. In addition, antistatic ability and saturation current stability of the LED may also be enhanced so as to improve reliability thereof.

In the description above, for the purposes of explanation, numerous specific details have been set forth in order to provide a thorough understanding of the embodiments. It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A light-emitting diode (LED), comprising:
a substrate which has a surface with an upper edge, a lower edge, and two opposing side edges that extend between said upper and lower edges;
an epitaxial structure which is disposed on said surface of said substrate and which includes a first semiconductor layer, a second semiconductor layer and an active layer interposed between said first and second semiconductor layers;
a first electrode which is disposed on said first semiconductor layer; and
a second electrode which is disposed on said second semiconductor layer, and which includes a main portion and two extension portions that extend away from said main portion, wherein a projection of said main portion on said surface is more proximal to said lower edge than to said upper edge, and wherein a projection of each of said extension portions on said surface extends in an extension direction away from said lower edge toward a corresponding one of said side edges in such a manner that an included angle between a central axis perpendicular to said bottom edge and a tangent line of any point on said projection of each of said extension portions on said surface is not greater than 90° and increases along the extension direction.

2. The LED of claim 1, wherein said projection of each of said extension portions on said surface has two opposite sides, one of said sides concavely facing said lower edge, and the other one of said sides convexly facing said upper edge.

3. The LED of claim 1, wherein each of said extension portions is formed as an arc structure.

4. The LED of claim 2, wherein each of said extension portions has a radius of curvature that is not greater than 100 μm.

5. The LED of claim 2, wherein each of said extension portions has a radius of curvature that is constant along the extension direction.

6. The LED of claim 2, wherein each of said extension portions has a radius of curvature that increases along the extension direction.

7. The LED of claim 1, wherein along the extension direction, each of said extension portions sequentially includes a curved segment and a first straight segment.

8. The LED of claim 7, wherein each of said extension portions further includes a second straight segment that is connected to said curved segment opposite to said first straight segment.

9. The LED of claim 1, wherein along the extension direction, each of said extension portions sequentially includes a curved segment and a straight segment.

10. The LED of claim 1, wherein each of said extension portions includes a plurality of straight segments with different slopes which are consecutively connected to each other along the extension direction.

11. The LED of claim 1, wherein each of said extension portions independently extends from said main portion.

12. The LED of claim 1, wherein a cross section of each of said extension portions perpendicular to the extension direction has a bottom width proximal to said epitaxial structure which ranges from 2 μm to 10 μm.

13. The LED of claim 1, wherein said upper edge and said lower edge of said surface are spaced apart from each other by a distance H, and a distance between said lower edge and a terminal point on the projection of each of said extension portions that is farthest from said main portion ranges from 0.15 H to 0.6 H.

14. The LED of claim 1, wherein a minimal distance between a terminal point on the projection of each of said extension portions that is farthest from said main portion and a respective one of said side edges ranges from 5 μm to 40 μm.

15. The LED of claim 1, wherein the central axis passes through a centroid of said surface, and a projection of said main portion on said substrate lies on the central axis.

16. The LED of claim 1, wherein the central axis passes through a centroid of said surface, and a projection of said first electrode on said substrate lies on the central axis.

17. The LED of claim 1, wherein said first electrode includes a main portion and two extension portions extending from said main portion, a projection of said main portion of said first electrode on said substrate lying on the central axis.

18. The LED of claim 1, further comprising:
an insulating layer which is disposed over said epitaxial structure, and which is formed with a first through hole partially exposing said first electrode and a second through hole partially exposing said second electrode;
a first pad electrode which is disposed on said insulating layer and which fills said first through hole to be electrically connected to said first electrode; and
a second pad electrode which is disposed on said insulating layer and which fills said second through hole to be electrically connected to said second electrode.

19. The LED of claim 1, wherein a length of each of the side edges may be not greater than twice of a length of each of the upper and lower edges.

20. A light-emitting device, comprising at least one LED of claim 1.
